(19) United States
(12) Patent Application Publication
(10) Pub. No.: US 2013/0160848 A1
(43) Pub. Date: Jun. 27, 2013

(54) PHOTOELECTRIC CONVERSION DEVICE

(71) Applicant: SANYO ELECTRIC CO., LTD., Osaka (JP)

(72) Inventors: Toshikazu OONO, Mizuho-shi (JP); Shigeo Yata, Ogaki-shi (JP); Masao KANDA, Osaka (JP)

(73) Assignee: SANYO ELECTRIC CO., LTD., Osaka (JP)

(21) Appl. No.: 13/773,285

(22) Filed: Feb. 21, 2013

Related U.S. Application Data
(63) Continuation of application No. PCT/JP2012/060839, filed on Apr. 23, 2012.

(30) Foreign Application Priority Data
May 13, 2011 (JP) 2011-107762
Oct. 31, 2011 (JP) 2011-239076
Nov. 29, 2011 (JP) 2011-259772

(51) Int. Cl. H01L 31/0224

(52) U.S. Cl. CPC H01L 31/022425
USPC 136/256

(57) ABSTRACT

A photoelectric conversion device is provided with a substrate (20), a surface electrode layer (22) formed on the substrate (20), and an a-Si unit (202) and μ-Si unit (204) which are a photoelectric conversion unit formed on the surface electrode layer (22). The surface electrode layer (22) is constituted of a transparent conductive film containing a dopant and has a light scattering region (22a) having a first dopant concentration and having film thickness of half or more of the total film thickness of the surface electrode layer (22) and a contact region (22b) positioned on the photoelectric conversion unit side of the light scattering region (22a) and containing a transition region (X) in which the dopant concentration continuously increases from the light scattering region (22a).

### CROSS-REFERENCE TO RELATED APPLICATION

The present application is a continuation application of International Application No. PCT/JP2012/060839, filed Apr. 23, 2012, the entire contents of which are incorporated herein by reference and priority to which is hereby claimed. The PCT/JP2012/060839 application claimed the benefit of the date of the earlier filed Japanese Patent Application No. 2011-107762 filed May 13, 2011, Japanese Patent Application No. 2011-239076 filed Oct. 31, 2011, and Japanese Patent Application No. 2011-259772 filed Nov. 29, 2011, the entire contents of which is incorporated herein by references, and priorities to which are hereby claimed.

### TECHNICAL FIELD

The present invention relates to a photoelectric conversion device.

### BACKGROUND ART

Photoelectric conversion devices in which semiconductor thin films such as amorphous, microcrystal, and the like, are layered are being used as a power generation system that uses sunlight.

FIG. 19 is a cross sectional view schematically illustrating a basic structure of a photoelectric conversion device 100. The photoelectric conversion device 100 is formed by stacking, on a substrate 10 formed of glass or the like, a surface electrode layer 12, a photoelectric conversion unit 14, and a back surface electrode layer 16. If the substrate 10 is a transparent substrate and light is caused to enter from the substrate 10 side, the surface electrode layer 12 is formed of a transparent conductive film (TCO). Further, while the back surface electrode layer 16 often has a layered structure formed of a transparent conductive film and a metal film, it may have a structure in which a reflective sealing member is disposed on a transparent conductive film and a metal film is not formed. Transparent conductive films that are to be formed as the surface electrode layer 12 and the back surface electrode layer 16 are generally formed by using an MOCVD method and a sputtering method.

Here, JP 2008-277387 A discloses a structure of a surface electrode layer 12 including, from a substrate 10 side, a first transparent electrode layer having surface depressions and projections in which zinc oxide is doped with impurities, and a low-resistance second transparent electrode layer containing zinc oxide which is doped with impurities at a concentration which is higher than that of the first transparent electrode layer. In this case, it is preferable that the second transparent electrode layer is formed at a deposition rate which is less than or equal to half the deposition rate for the first transparent electrode layer.

JP 2007-288043 A discloses a photovoltaic device in which a surface electrode layer 12 is formed on a primary coat, and discloses that it is preferable that the surface electrode layer 12 is formed of zinc oxide including boron (B) atoms of 2×10¹⁹/cm³ or over, and hydrogen (H) atoms of 2×10²⁰ cm³ or over as the maximum values of the atomic density respectively measured by SIMS, and that a ratio of B atom density/H atom density is varied to have a minimum value at a predetermined position of the transparent conductive film in the thickness direction.

Also, JP 2009-111183 A discloses that it is preferable that in a surface electrode layer 12, the hydrogen (H) atom concentration, at a predetermined position from an interface on the side far from a base layer, is lower than the H atom concentration at a predetermined position from an interface on the side of the base layer, and the boron (B) atom concentration, at a predetermined position from the interface on the side far from the base layer, is lower than the B atom concentration at a predetermined position from the interface on the side of the base layer.

### DISCLOSURE OF THE INVENTION

### Technical Problems

However, as the properties of the surface electrode layer significantly affect the photoelectric conversion efficiency in a photoelectric conversion device, it is required that the surface electrode layer especially has small contact resistance with respect to a photoelectric conversion unit, high electric conductivity, low light absorption index, and high light scattering effect.

### Solution to Problems

In accordance with one aspect of the invention, there is provided a photoelectric conversion device, including a substrate, a surface electrode layer which is formed on the substrate, and a photoelectric conversion unit which is formed on the surface electrode layer, wherein the surface electrode layer is formed of a transparent conductive film including dopant, and includes a first transparent conductor region having a first dopant concentration and having a film thickness which is half a total film thickness of the surface electrode layer or more and a second transparent conductor region which is located toward the photoelectric conversion unit with respect to the first transparent conductor region, the second transparent conductor region including a transition region in which a dopant concentration increases continuously from the first transparent conductor region.

### Advantageous Effects of Invention

The present invention proposes a transparent electrode layer having low contact resistance, high electrical conductivity, low light absorption index, and high light scattering effect, so that the performance of a photoelectric conversion device including such a transparent electrode layer can be improved.

### BRIEF DESCRIPTION OF THE DRAWINGS

FIG. 1

Cross sectional view illustrating a structure of a photoelectric conversion device according to a first embodiment.

FIG. 2

View illustrating a structure of a surface electrode layer according to the first embodiment.

FIG. 3

View indicating a relationship between a flow rate of doping gas and resistivity of a transparent conductive film according to the first embodiment.

FIG. 4

View indicating the flow rate of doping gas and transmittance of the transparent conductive film according to the first embodiment.

FIG. 5

View indicating the flow rate of doping gas and the Haze rate of the transparent conductive film according to the first embodiment.

FIG. 6

View indicating a structure of the surface electrode layer and the dopant concentration according to the first embodiment.

FIG. 7

View indicating a structure of the surface electrode layer and the dopant concentration according to the first embodiment.

FIG. 8

View indicating the transmittance of a light scattering region and a conductive region according to the first embodiment.

FIG. 9

Cross sectional view illustrating a structure of a photovoltaic device according to a second embodiment.

FIG. 10

View illustrating a structure of a surface electrode layer according to the second embodiment.

FIG. 11

View showing a structure of the surface electrode layer and the dopant concentration according to the second embodiment.

FIG. 12

View showing transmittance of the surface electrode layer according to the second embodiment.

FIG. 13

Cross sectional view illustrating a structure of a photovoltaic device according to a third embodiment.

FIG. 14

View illustrating a structure of a surface electrode layer according to the third embodiment.

FIG. 15

View showing a structure of the surface electrode layer and the dopant concentration according to the third embodiment.

FIG. 16

Graph showing a relationship between the film thickness of the surface electrode layer and an increase in haze rate.

FIG. 17

Graph showing a change in haze rate due to a combination of a first transparent conductive region and a second transparent conductive region according to the third embodiment.

FIG. 18

View showing the effect of increase in the haze rate of the surface electrode layer according to the third embodiment.

FIG. 19

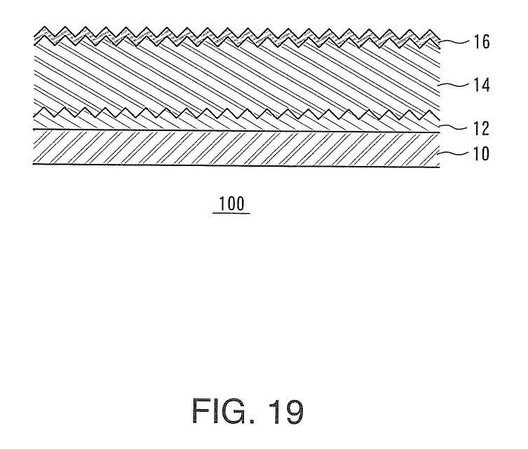

Cross sectional view illustrating a structure of a conventional photovoltaic device.

### BEST MODE FOR CARRYING OUT THE INVENTION

### First Embodiment

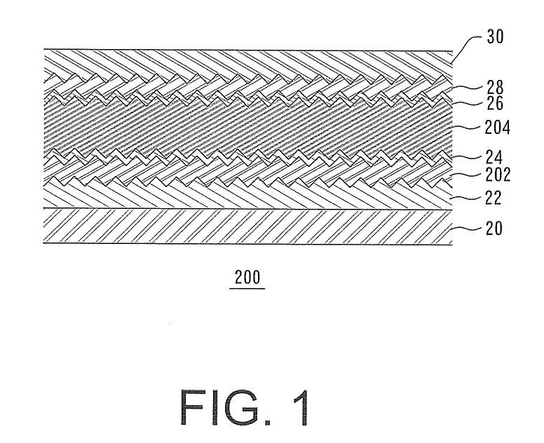

A photoelectric conversion device 200 according to the present embodiment has a layered structure as illustrated in FIG. 1. Specifically, with a substrate 20 being on a light incidenting side and starting from the light incidenting side, a surface electrode layer 22, an amorphous silicon photoelectric conversion unit (a-Si unit) 202 having a wide band gap as a top cell, an intermediate layer 24, a microcrystalline silicon photoelectric conversion unit (μc-Si unit) 204 having a band gap which is narrower than that of the a-Si unit 202 as a bottom cell, a back surface electrode layer 26, a filler member 28, and a back sheet 30 are stacked.

While in the present embodiment a tandem type photoelectric conversion device in which the a-Si unit 202 and the μc-Si unit 204 are stacked as a photoelectric conversion unit which is a power generation layer will be described as an example, the scope to which the present invention can be applied is not limited to this example, and the present invention may be a single type photoelectric conversion device or a multilayer photoelectric conversion device.

As the substrate 20, a glass substrate, a plastic substrate, and the like, which is formed of a material having transmittance at least in the visible light wavelength region, may be applied.

The surface electrode layer 22 is formed on the substrate 20. The surface electrode layer 22 is formed of a single layer transparent conductive film. For the transparent conductive film, a single body (single layer) of a transparent conductive oxide (TCO), in which tin oxide (SnO₂), zinc oxide (ZnO), indium tin oxide (ITO), and the like, is doped with tin (Sn), antimony (Sb), fluorine (F), aluminum (Al), and the like, is preferably used. In particular, zinc oxide (ZnO) is preferable because it has high transparency, low resistivity, and excellent plasma resistance.

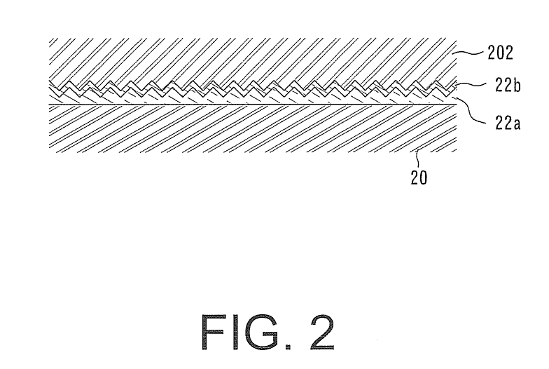

According to the present embodiment, as illustrated in FIG. 2, the surface electrode layer 22 includes a structure in which a light scattering region 22a and a contact region 22b are stacked sequentially from the substrate 20 side. The light scattering region 22a is a region which is provided to make incidenting light scatter to achieve the light confinement effect with respect to the photoelectric conversion device 200 and to enhance the efficiency of light of the surface electrode layer 22 as a whole. The contact region 22b, which is located toward the photoelectric conversion unit with respect to the light scattering region 22a, is a region which is provided to make electrical contact with the a-Si unit 202, which is a photoelectric conversion unit, preferable and also to obtain high electric conductivity of the surface electrode layer 22 as a whole.

The light scattering region 22a and the contact region 22b can be formed by chemical vapor deposition (CVD). If the light scattering region 22a and the contact region 22b are formed of zinc oxide (ZnO), these regions can be formed by low-pressure metal-organic chemical vapor deposition (LP-MOCVD) in which source gas formed of a mixture of diethyl zinc (DEZ: (C₂H₅)₂Zn), water, and doping gas is used. Dimethyl zinc may be used as source gas for zinc. Diborane (B₂H₆) can be used as the doping gas. Under the condition that the substrate temperature is 150° C. or higher, and the pressure is 0.1 mbar or more and 10 mbar or less, the doping gas is introduced while DEZ and water ae supplied after being vaporized by heating and evaporation, bubbling, spraying, and the like. The total film thickness of the surface electrode layer 22 is preferably 1 μm or more and 5 μm or less.

The light scattering region 22a is formed such that the dopant concentration in the film is lower than that of the contact region 22a. More specifically, the light scattering region 22a is formed with the doping gas being decreased with respect to the doping gas in the contact region 22b. For example, the light scattering region 22a and the contact region 22b can be formed under the film forming conditions indicated in Table 1. It is preferable that the light scattering region 22a and the contact region 22b are formed by continuous film forming as a single layer transparent conductive film. In particular, it is preferable that, in order to take over the crystallinity of the light scattering region 22a which serves as a base layer during film formation to make the grain size of the contact region 22b larger, the flow rate of the doping gas is changed in the vicinity of the boundary between the light scattering region 22a and the contact region 22b to obtain continuous film forming conditions, so that the film is formed such that the dopant concentration within the contact region 22b increases slightly in the film thickness direction. Specifically, the contact region 22b is configured so as to include a transition region X in which the dopant concentration continuously increases in the film thickness direction from the light scattering region 22a side. The transition region X will be described later below.

TABLE 1

| | | | gas flow rate |
|---|---|---|---|
| | temperature (° C.) | pressure (mbar) | (sccm) |
| light scattering | 180 | 0.5 | (C₂H₅) ₂Zn: 650 |
| region 22a | | | H₂O: 750 |
| | | | 1% B₂H₆/H₂: 125 |
| | | | H₂: 100 |
| contact region | 180 | 0.5 | (C₂H₅) ₂Zn: 650 |
| 22b | | | H₂O: 750 |
| | | | 1% B₂H₆/H₂: 300 |
| | | | H₂: 100 |

When the photoelectric conversion device 200 is configured such that a plurality of cells are connected in series, the surface electrode layer 22 is patterned in a strip shape. For example, it is possible to pattern the surface electrode layer 22 in a strip shape by using a YAG laser having a wavelength of 1064 nm, an energy density of 13 J/cm², and a pulse frequency of 3 kHz.

On the surface electrode layer 22, a p-type silicon thin film, an i-type silicon thin film, and n-type silicon thin film are sequentially stacked to form the a-Si unit 202. The a-Si unit 202 can be formed by plasma chemical vapor deposition (CVD method) in which mixed gas formed by mixing silicon-containing gas such as silane (SiH₄), disilane (Si₂H₆), dichlorosilane (SiH₂Cl₂), and the like, carbon-containing gas such as methane (CH₄), p-type dopant-containing gas such as diborane (B₂H₆), n-type dopant-containing gas such as phosphine (PH₃), and diluents gas such as hydrogen (H₂) is used to form plasma for film formation.

For the plasma CVD, an RF plasma CVD of 13.56 MHz is preferably applied, for example. The RF plasma CVD can be a parallel plate type CVD. A structure in which a gas shower hole through which the mixed gas of a raw material is supplied is provided on a side of parallel plate electrode where the substrate 20 is not formed. It is preferable that the power density of plasma is 5 mW/cm² or greater and 300 mW/cm² or less.

As the p-type layer, an amorphous silicon layer, a microcrystalline silicon thin film, a microcrystalline silicon carbide, and the like, having a film thickness of 5 nm or more and 50 nm or less, to which p-type dopant (boron or the like) is added is provided as a single layer or in a layered structure. The film property of the p-type layer can be varied by adjusting the mixture ratio of the silicon-containing gas, the p-type dopant-containing gas, and the diluent gas, the pressure, and the high frequency power for plasma generation. The i-type layer is an amorphous silicon film formed on the p-type layer and having a film thickness of 50 nm or more and 500 nm or less, to which no dopant is added. The film property of the i-type layer can be varied by adjusting the mixture ratio of the silicon-containing gas and the diluent gas, the pressure, and the high frequency power for plasma generation. The i-type layer serves as a power generation layer of the a-Si unit 202. The n-type layer is an n-type microcrylstalline silicon layer (n-type μc-Si:H) formed on the i-type layer and having a film thickness of 10 nm or more and 100 nm or less, to which n-type dopant (phosphor or the like) is added. The film property of the n-type layer can be varied by adjusting the mixture ratio of the silicon-containing gas, the carbon-containing gas, the n-type dopant-containing gas, and the diluent gas, the pressure, and the high frequency power for plasma generation. While these layers of the a-Si unit 202 are not limited to the above examples, the a-Si 202 can be formed under the film forming conditions indicated in Table 2, for example.

TABLE 2

| | | substrate | | | | |
|---|---|---|---|---|---|---|
| | | tempera- | gas flow | reaction | RF | film |
| | | ture | rate | pressure | power | thickness |
| | layer | (° C.) | (sccm) | (Pa) | (W) | (nm) |
| a-Si | p-type | 180 | SiH₄: 300 | 106 | 10 | 15 |
| unit 202 | layer | | CH₄: 300 | | | |
| | | | H₂: 2000 | | | |
| | | | B₂H₆: 3 | | | |
| | i-type | 180 | SiH₄: 300 | 106 | 20 | 250 |
| | layer | | H₂: 2000 | | | |
| | n-type | 180 | SiH₄: 300 | 133 | 20 | 30 |
| | layer | | H₂: 2000 | | | |
| | | | PH₃: 5 | | | |

The intermediate layer 24 is formed on the a-Si unit 202. For the intermediate layer 24, transparent conductive oxide (TCO) such as zinc oxide (ZnO), silicon oxide (SiOx), and the like is preferably used. The intermediate layer 24 can be formed, for example, by sputtering. The film thickness of the intermediate layer 24 is preferably in a range of 10 nm or more and 200 nm or less. Further, the intermediate layer 24 can be omitted.

On the intermediate layer 24, a p-type layer, an i-type layer, and an n-type layer are sequentially stacked to form the μc-Si unit 204. The μc-Si unit 204 can be formed by plasma chemical vapor deposition (CVD method) in which mixed gas formed by mixing silicon-containing gas such as silane (SiH₄), disilane (Si₂H₆), dichlorosilane (SiH₂Cl₂), and the like, carbon-containing gas such as methane (CH₄), p-type dopant-containing gas such as diborane (B₂H₆), n-type dopant-containing gas such as phosphine (PH₃), and diluent gas such as hydrogen (H₂) is used to form plasma for film formation.

As in the case of the a-Si unit 202, for the plasma CVD, an RF plasma CVD of 13.56 MHz is preferably applied, for example. The RF plasma CVD can be a parallel plate type CVD. A structure in which a gas shower hole through which the mixed gas, which is a raw material, is supplied is provided on a side of the parallel plate electrode where the substrate 20 is not formed. It is preferable that the power density of plasma is 5 mW/cm² or greater and 300 mW/cm² or less.

The p-type layer is a microcrystalline silicon layer (μc-Si:H) having a film thickness of 5 nm or more and 50 nm or less, to which p-type dopant (boron or the like) is added. The film property of the p-type layer can be varied by adjusting the mixture ratio of the silicon-containing gas, the p-type dopant-containing gas, and the diluent gas, the pressure, and the high frequency power for plasma generation.

The i-type layer is a microcrystalline silicon layer (μc-Si:H) formed on the p-type layer and having a film thickness of 0.5 μm or more and 5 μm or less, to which no dopant is added. The film property of the i-type layer can be varied by adjusting the mixture ratio of the silicon-containing gas and the diluent gas, the pressure, and the high frequency power for plasma generation.

The n-type layer is formed by stacking a microcrystalline silicon layer (n-type μc-Si:H) having a film thickness of 5 nm or more and 50 nm or less, to which n-type dopant (phosphor or the like) is added. The film property of the n-type layer can be varied by adjusting the mixture ratio of the silicon-containing gas, the n-type dopant-containing gas, and the diluent gas, the pressure, and the high frequency power for plasma generation. While these layers of the μc-Si unit 204 are not limited to the above examples, the μc-Si 204 can be formed under the film forming conditions indicated in Table 3, for example.

TABLE 3

| | | substrate | | | | |
|---|---|---|---|---|---|---|
| | | tempera- | gas flow | reaction | RF | film |
| | | ture | rate | pressure | power | thickness |
| | layer | (° C.) | (sccm) | (Pa) | (W) | (nm) |
| μc-Si | p-type | 180 | SiH₄: 10 | 106 | 10 | 30 |
| unit 204 | layer | | H₂: 2000 | | | |
| | | | B₂H₆: 3 | | | |
| | i-type | 180 | SiH₄: 100 | 133 | 20 | 2000 |
| | layer | | H₂: 2000 | | | |
| | n-type | 180 | SiH₄: 10 | 133 | 20 | 20 |
| | layer | | H₂: 2000 | | | |
| | | | PH₃: 5 | | | |

When a plurality of cells are connected in series, the a-Si unit 202, the intermediate layer 24, and the μc-Si unit 204 are patterned in a strip shape. A YAG laser is applied to a position which is laterally separated from where the surface electrode layer 22 is patterned by 50 μm to form a slit, and the a-Si unit 202 and the μc-Si unit 204 are patterned in a strip shape. The YAG laser having an energy density of 0.7 J/cm² and a pulse frequency of 3 kHz, for example, is preferably used.

On the μc-Si unit 204, the back surface electrode layer 26 is formed. The back surface electrode layer 26 preferably has a layered structure of transparent conductive oxide (TCO) and a reflective metal. As the transparent conductive oxide (TCO), tin oxide (SnO₂), zinc oxide (ZnO), indium tin oxide, and the like is used. Further, as the reflective metal, a metal such as gold (Ag), aluminum (Al), and the like, is used. The transparent conductive oxide (TCO) and the reflective metal can be formed by sputtering, for example. It is preferable that the back surface electrode layer 26 has a total film thickness of about 1 μm. Further, it is preferable that the back surface electrode layer 26 includes depressions and projections so as to enhance the light confinement effect.

When the photoelectric conversion device 200 has a structure in which a plurality of cells are connected in series, the back surface electrode layer 26 is patterned in a strip shape. A YAG laser is applied to a position which is laterally 50 μm displaced from where the a-Si unit and the μc-Si unit 204 have been patterned to form a slit, and the back surface electrode layer 26 is patterned in a strip shape. The YAG laser having an energy density of 0.7 J/cm² and a pulse frequency of 4 kHz, for example, is preferably used.

Further, the surface of the back surface electrode layer 26 is covered with a back sheet 30 by using the filler member 28. The filler member 28 and the back sheet 30 can be a resin material such as EVA, polyimide, and the like. Consequently, intrusion of water content or the like into the power generation layer of the photoelectric conversion device 200 can be prevented.

Next, the advantages which can be obtained by forming the surface electrode layer 22 as a single layer transparent conductive film including the light scattering region 22a and the contact region 22b will be described.

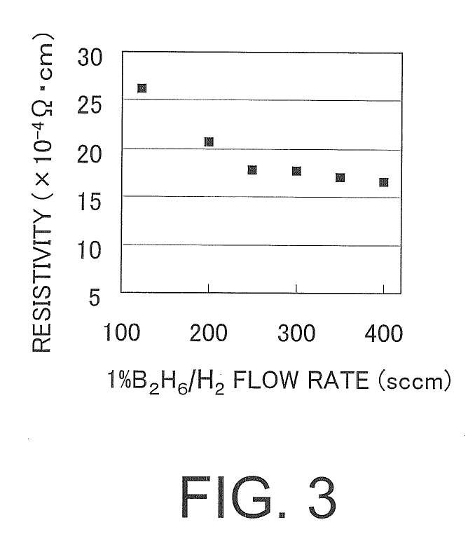

FIGS. 3 to 5 indicate relationships between the introduction quantity of dopant gas and the resistivity, light transmittance, and Haze rate, respectively, of a single film of zinc oxide (ZnO) doped with boron (B) which is formed on a glass substrate. Here, the film forming conditions are the same as those in Table 1 except for the introduction quantity of dopant gas.

Here, the Haze rate was used as a performance index of the depressions and projections of the transparent electrode film. The Haze rate is represented by (diffusion transmittance/total transmittance)×100[%] (JIS K7136). Measurements performed with a Haze meter by using a D65 light source or a C light source are generally used as a simple evaluation method of the Haze rate.

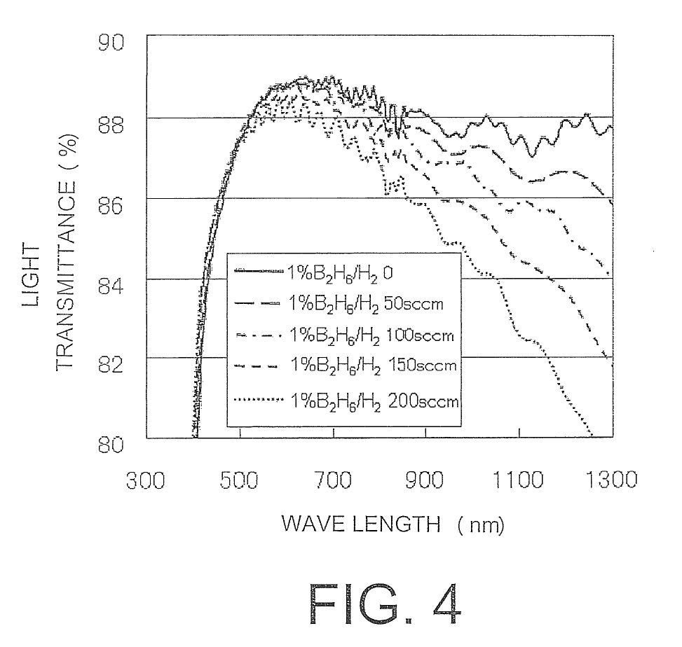

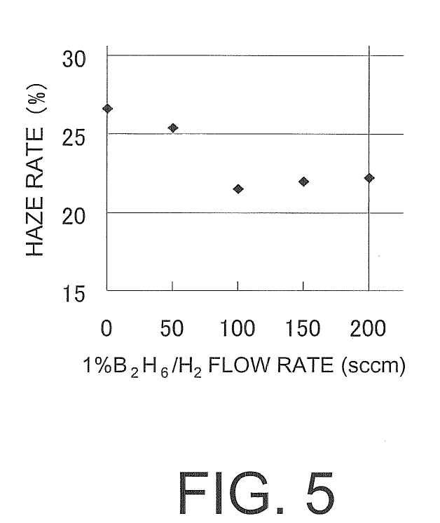

Referring to FIG. 3, the resistivity decreases as the introduction quantity of dopant gas increases. On the other hand, referring to FIG. 4, the light transmittance decreases as the introduction quantity of dopant gas increases, and particularly, the degree of decrease is significant in the wavelength region of 500 nm or greater. Further, referring to FIG. 5, the Haze rate decreases slightly as the introduction quantity of dopant gas increases.

As illustrated in FIGS. 3 to 5, as the dopant concentration increases, the resistivity of a transparent conductive film decreases, and the light transmittance and the light scattering effect also decrease. Accordingly, in the present embodiment, in order to obtain the high electrical resistivity, low contact resistance with the photoelectric conversion unit, low light absorption index, and high light scattering effect of the surface electrode layer 22 as a whole, the surface electrode layer 22 is formed as a single layer transparent conductive film including the light scattering region 22a and the contact region 22b.

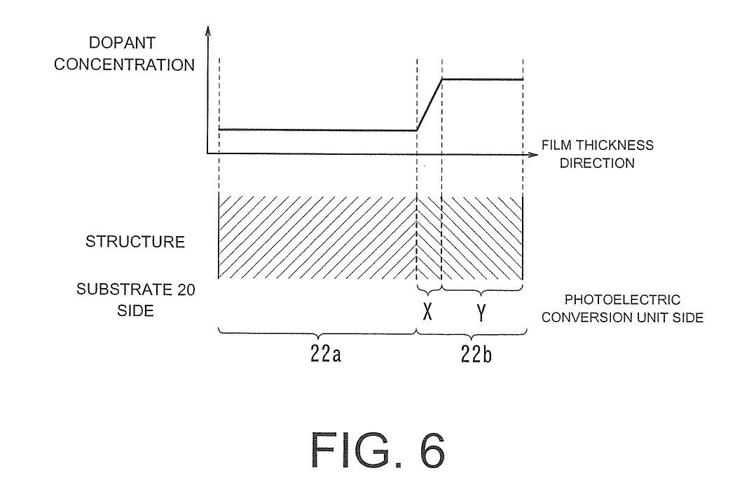

Here, the film thickness of the light scattering region 22a is preferably more than or equal to half the total film thicknesses of the light scattering region 22a and the contact region 22b, as illustrated in FIG. 6. With this configuration, it is possible to suppress the absorption of light in the contact region 22b to thereby increase the quantity of light that transmits the surface electrode layer 22 and is introduced into the photoelectric conversion unit, so that the photoelectric conversion efficiency of the photoelectric conversion device 200 can be increased.

Further, the Haze rate of the transparent conductive film increases as the dopant concentration is lower. It can be assumed that this is because the growth of crystal grain during film formation is accelerated to make the grain size large. More specifically, by forming the light scattering region 22a having the dopant concentration in the film which is lower than that of the contact region 22b during the initial stage of film formation of the surface electrode layer 22 on the substrate 20, the grain size of the transparent conductive film can be increased compared to when film formation is performed under the conditions for the contact region 22b. As the light scattering region 22a which is formed as described above is provided, the light incidenting the photoelectric conversion device 200 is scattered and introduced into the photoelectric conversion unit, so that the light confinement effect can be increased and the photoelectric conversion efficiency of the photoelectric conversion device 200 can be enhanced.

Here, the contact region 22b is formed such that the contact region 22b takes over crystallinity of the light scattering region 22a serving as a base layer at the time of forming the contact region 22b on the light scattering region 22a, and the grain size of the contact region 22b is large. If the change in the dopant concentration is steep at the boundary between the light scattering region 22a and the contact region 22b as in the conventional transparent conductive film formed by layered films having different dopant concentrations, it is difficult to allow the crystallinity of the light scattering region 22a to be taken over at the time of forming the contact region 22b, and the grain size of the crystal grain of the contact region 22b is small. It is therefore preferable to provide a transition region X in which the dopant concentration changes gently in the film thickness direction in the vicinity of the boundary between the light scattering region 22a and the contact region 22b, as in the present embodiment.

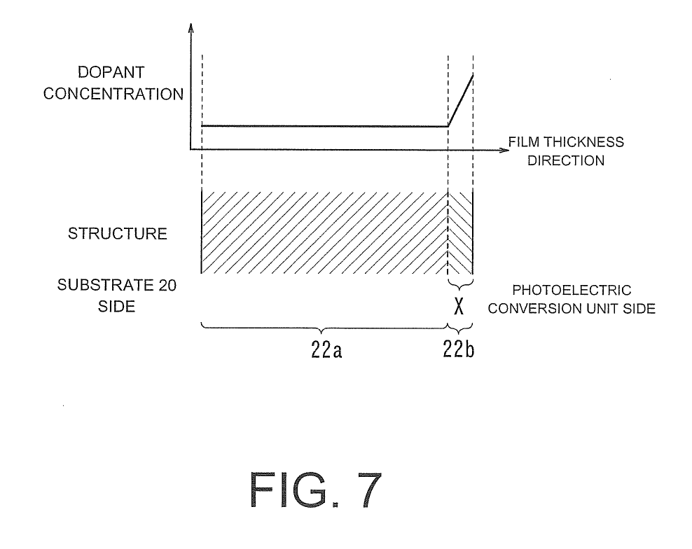

The transition region X is continuously formed such that the dopant concentration within the contact region 22b increases gently in the film thickness direction by changing the flow rate of the doping gas in the vicinity of the boundary between the light scattering region 22a and the contact region 22b. It is also possible to perform the change of the doping gas stepwise and control the concentration of the doping gas to gradually increase. More specifically, as illustrated in FIG. 6, it is preferable that the film thickness of the transition region X is more than or equal to one-twentieth of the total thicknesses of the light scattering region 22a and the contact region 22b. Further, because the light transmittance is lowered when the film thickness of the transition region X is too great, it is preferable that the film thickness of the transition region X is less than or equal to one-tenth the total thickness of the light scattering region 22a and the contact region 22b. Here, the contact region 22b may include a stable region Y in which the dopant concentration is more stable than in the transition region X, as illustrated in FIG. 6, so long as the above conditions are satisfied, or all the region of the contact region 22b may be the transition region X as illustrated in FIG. 7.

At this time, the dopant concentration in the light scattering region 22a changes less and is therefore more stable than the dopant concentration in the transition region X of the contact region 22b. In other words, the inclination of the dopant concentration in the light scattering region 22a is smaller than the inclination of the dopant concentration in the transition region X and has an inflection point at the boundary of the light scattering region 22a and the contact region 22b. The dopant concentration in the stable region Y of the contact region 22b changes less and is therefore more stable than the dopant concentration in the transition region X of the contact region 22b. In other words, the inclination of the dopant concentration in the light scattering region 22a is smaller than the inclination of the change in the transition region X and has an inflection point at the boundary therebetween.

The dopant concentration within the surface electrode layer 22 can be measured by a secondary ion mass spectroscopy (SIMS). At this time, it is preferable to perform the measurement by using ion milling or the like from the substrate 20 side, in order to avoid effects of the depressions and projections of the crystal grain of the film.

Next, under the film forming conditions indicated in Table 1, the light scattering region 22a and the contact region 22b were formed such that the total film thickness was 2.0 μm. Then, the Haze rate and the total transmittance were measured for cases in which the ratios of the thicknesses of these regions were 1:1 and 1:3, respectively. Further, in a Comparative Example, the light scattering region 22a was not formed and only the contact region 22b was formed to have a film thickness of 2.0 μm.

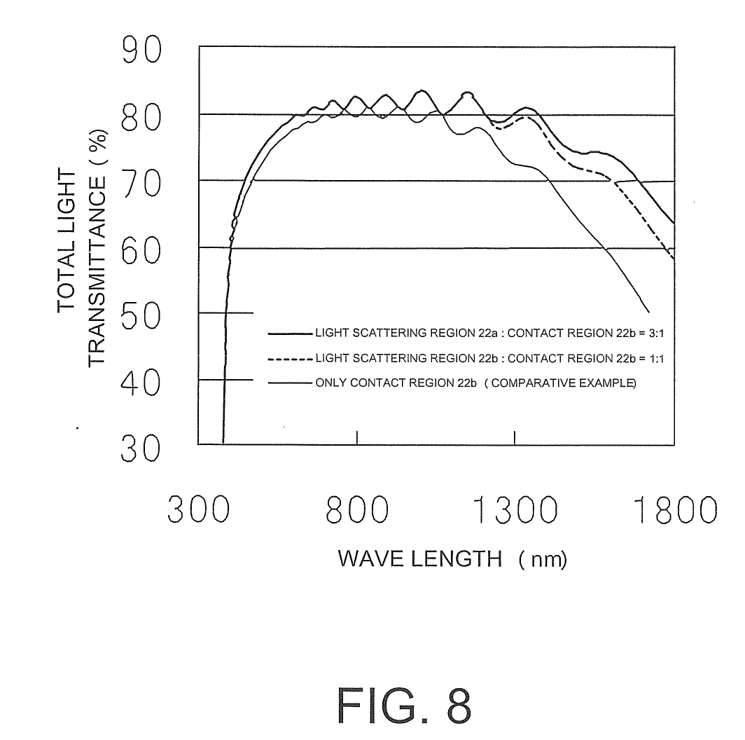

As a result of the measurement, the Haze rate was substantially constant with both of the film thickness ratios and was not very different from that in the Comparative Example. The total transmittance increases as the film thickness of the light scattering region 22a increases, as illustrated in FIG. 8.

Table 4 shows properties of the photoelectric conversion device 200 which was formed under the film forming conditions in the above embodiment. Here, in Examples 1 to 3, the surface electrode layer 22 was formed under the film forming conditions illustrated in Table 1 and the ratios of the film thicknesses of the light scattering region 22a and the contact region 22b were set to 1:1, 2:1, and 3:1, respectively. In Comparative Examples 1 and 2, only the contact region 22b or only the light scattering region 22a was formed, respectively. Also, in all the examples, the total film thickness of the surface electrode layer 22 was 2 μm, and the thickness of the transition region X was in the range of one-twentieth or more and one-tenth or less of the total film thickness. Further, Table 4 indicates values that are normalized with reference to the measurement values in Comparative Example 2 being 1.

TABLE 4

| | | film | open- | short- | | |
|---|---|---|---|---|---|---|
| | | thick- | circuit | circuit | fill | effi- |
| | | ness | voltage | current | factor | ciency |
| | | ratio | (Voc) | (Isc) | (FF) | (Eff) |
| Comparative | only contact | 0:1 | 1.06 | 0.96 | 1.04 | 1.08 |
| Example 1 | region 22b | | | | | |
| Example 1 | light scattering | 1:1 | 1.06 | 0.98 | 1.06 | 1.11 |
| | region | | | | | |
| | 22a:contact | | | | | |
| | region 22b | | | | | |
| Example 2 | light scattering | 2:1 | 1.07 | 1.00 | 1.06 | 1.12 |
| | region | | | | | |
| | 22a:contact | | | | | |
| | region 22b | | | | | |
| Example 3 | light scattering | 3:1 | 1.06 | 1.00 | 1.04 | 1.11 |
| | region | | | | | |
| | 22a:contact | | | | | |
| | region 22b | | | | | |
| Comparative | only light | 1:0 | 1 | 1 | 1 | 1 |
| Example 2 | scattering | | | | | |
| | region 22a | | | | | |

When compared to Comparative Example 2, the open-circuit voltage was higher in all of Examples 1 to 3; the short-circuit current was lower in Example 1 and was the same as that in Comparative 2 in Examples 2 and 3; the fill factor (FF) was higher in all of Examples 1 to 3; and the efficiency was higher in all of Examples 1 to 3. It can be assumed that the efficiency was the best in Example 2 because, as the light scattering region 22a becomes thinner, the short-circuit current lowers with the decrease in the light scattering effect and the increase in the light absorption, and as the contact region 22b becomes thinner, the fill factor is lowered with the increase in the resistance of the surface electrode layer 22 and the contact resistance with the light conversion unit.

### Second Embodiment

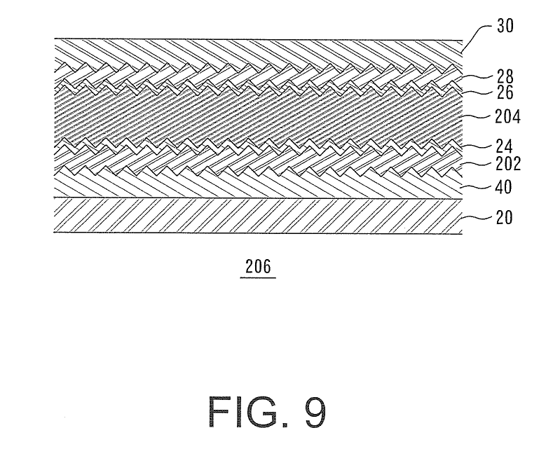

A photovoltaic device 206 according to the second embodiment has a layered structure as illustrated in FIG. 9. Specifically, with a substrate 20 being on a light incidenting side and starting from the light incidenting side, a surface electrode layer 40, an amorphous silicon photoelectric conversion unit (a-Si unit) 202 having a wide band gap as a top cell, an intermediate layer 24, a microcrystalline silicon photoelectric conversion unit (μc-Si unit) 204 having a band gap which is narrower than that of the a-Si unit 202 as a bottom cell, a back surface electrode layer 26, a filler member 28, and a back sheet 30, are stacked.

On the substrate 20, the surface electrode layer 40 is formed. The surface electrode layer 40 is formed of a single layer transparent conductive film. The transparent conductive film can be formed by a material and a manufacturing method which are similar to those of the surface electrode layer 22 described above.

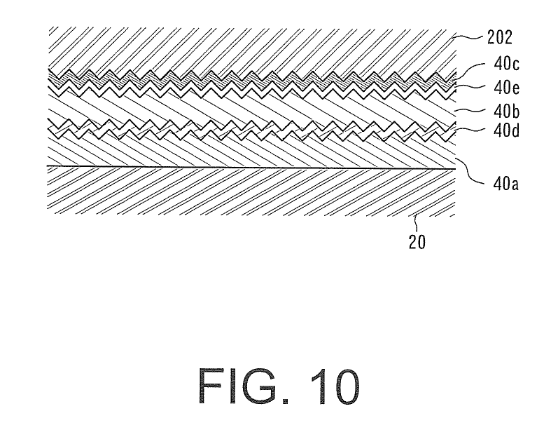

According to the present embodiment, as illustrated in FIG. 10, the surface electrode layer 40 includes a structure in which a first transparent conductive region 40a, a second transparent conductive region 40b, and a third transparent conductive region 40c are stacked sequentially from the substrate 20 side. The first transparent conductive region 40a is provided so as to increase total conductivity in the surface electrode layer 40. The second transparent conductive region 40b is provided so as to increase the crystal grain in the surface electrode layer 40 to enhance the light scattering effect due to an increase of depressions and projections in the texture structure. The third transparent conductive region 40c is provided so as to reduce an electrical contact resistance with the layer (the a-Si unit 202) to be formed on the surface electrode layer 40.

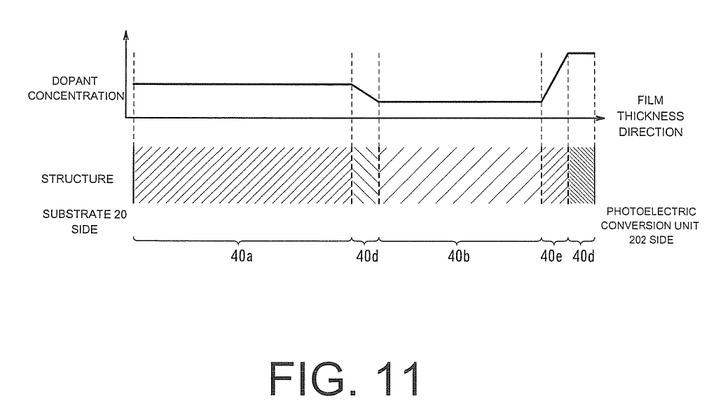

FIG. 11 illustrates a change in the dopant concentration in the film thickness direction of the surface electrode layer 40. It is preferable that the n-type dopant concentration in the film of the second transparent conducive region 40b is equal to or less than half the n-type dopant concentration of the first transparent conductive region 40a. However, the second transparent conductive region 40b may be a region in which no n-type dopant is introduced. Further, it is preferable that the n-type dopant concentration of the third transparent conductive region 40c is more than or equal to twice that of the first transparent conductive region 40a. The dopant concentration of the first transparent conductive region 40a is preferably 1×10²⁰/cm³ or more and 5×10²⁰/cm³ or less.

By setting the n-type dopant concentration in the film of the second transparent conductive region 40b to be equal to half the n-type dopant concentration of the first transparent conductive region 40a or less, the growth of crystal grain of the second transparent conductive region 40b is accelerated, so that the light scattering effect due to an increase of the depressions and projections of the texture structure can be enhanced. Further, by setting the n-type dopant concentration of the third transparent conductive region 40c to be equal to twice that of the first transparent conductive region 40a or more, an electrical contact property between the surface electrode layer 40 and the layer to be formed on the surface electrode layer (a-Si unit 202) can be enhanced.

Further, it is preferable to provide a first transition region 40d in which the dopant concentration is continuously or discontinuously reduced at the interface between the first transparent conductive region 40a and the second transparent conductive region 40b. Also, it is preferable to provide a second transition region 40e in which the dopant concentration is continuously or discontinuously increased at the interface between the second transparent conductive region 40b and the third transparent conductive region 40c. It can be considered that the first transition region 40d increases the adhesion property between the first transparent conductive region 40b serving as a base layer and the second transparent conductive region 40b, and also reduces the contact resistance at the interface thereof. It can be further considered that the second transition region 40e allows the third transparent conductive region 40c to take over the crystallinity or the like of the second transparent conductive region 40b serving as a base layer, so that the light scattering property of the texture structure of the third transparent conductive region 40c can be enhanced.

For example, after forming the first transparent conductive region 40a while introducing doping gas such that the dopant concentration is 1×10²⁰/cm³ or more and 5×10²⁰/cm³ or less, the second transparent conductive region 40b is formed by reducing the doping gas such that the dopant concentration of the second transparent conductive region 40b is less than or equal to half that of the first transparent conductive region 40a. Further, after forming the second transparent conductive region 40b, the third transparent conductive region 40c is formed by increasing the doping gas such that the dopant concentration of the third transparent conductive region 40c is more than or equal to twice that of the first transparent conductive region 40a. The first transition region 40d and the second transition region 40e can be formed with the introduction quantity of doping gas being varied continuously or discontinuously during the film formation.

The dopant concentration within the surface electrode layer 40 can be measured by the secondary ion mass spectroscopy (SIMS). At this time, it is preferable to perform the measurement by using ion milling or the like from the substrate 20 side, in order to avoid effects of the depressions and projections of the crystal grain of the film.

The total film thickness of the surface electrode layer 40 is set to about 1.7 μm. The film thicknesses of the first transition region 40d and the second transition region 40e are preferably 5% or more and 10% or less of the total film thickness of the surface electrode layer 40. If the film thicknesses of the first transition region 40d and the second transition region 40e are too small, it is difficult to obtain the advantage of increasing the adhesion property and the advantage of taking over the crystallinity, whereas if these thicknesses are too large, a reduction in the transmittance due to an increase in the film thickness can be caused. Further, the film thickness of the second transparent conductive region 40b is preferably 10% or more and 70% or less of the total film thickness of the surface electrode layer 40. If the film thickness of the second transparent conductive region 40b is too small, it is difficult to obtain the advantage of the crystal grain growth (=light scattering), whereas if the thickness thereof is too large, a reduction in the properties as a transparent conductive film due to an increase in the film thickness can be caused.

For example, it is preferable that the film thickness of the first transparent conductive region 40a is 800 nm, the film thickness of the second transparent conductive region 40b is 600 nm, and the film thickness of the third transparent conductive region 40c is 100 nm. If the first transition region 40d and the second transition region 40e are provided, the film thickness of each of these regions is preferably 100 nm.

Example film forming conditions of the surface electrode layer 40 are illustrated collectively in Table 5. Table 5 shows the dopant concentration ratios that are normalized with respect to the dopant concentration of the second transparent conductive region 40b (the first transparent conductive region 40a??) being 1.

TABLE 5

| | dopant | film | total film |
|---|---|---|---|
| | concentration | thickness | thickness |
| | ratio | (nm) | (μm) |
| first transparent conductive | 1 | 800 | 1.7 |
| region 40a | | | |
| first transition region 40d | — | 100 | |
| second transparent conductive | ½ or less | 600 | |
| region 40b | | | |
| second transition region 40e | — | 100 | |
| third transparent conductive | 2 or more | 100 | |
| region 40c | | | |

When the photovoltaic device 206 is configured such that a plurality of cells are connected in series, the surface electrode layer 40 is patterned in a strip shape. For example, it is possible to pattern the surface electrode layer 40 in a strip shape by using YAG laser having a wavelength of 1064 nm, an energy density of 13 J/cm², and a pulse frequency of 3 kHz.

On the surface electrode layer 40, a p-type layer silicon thin film, an i-type layer silicon thin film, and n-type layer silicon thin film are sequentially stacked to form the a-Si unit 202. On the a-Si unit 202, the intermediate layer 24 is formed. Further, the μc-Si unit 204 in which a p-type layer, an i-type layer, and a n-type layer are sequentially stacked is formed on the intermediate layer 24. The method of forming these layers is similar to that in the first embodiment and will not therefore be described.

When a plurality of cells are connected in series, the a-Si unit 202, the intermediate layer 24, and the μc-Si unit 204 are patterned in a strip shape. A YAG laser is applied to a position which is laterally displaced from where the surface electrode layer 22 has been patterned by 50 μm to form a slit, and the a-Si unit 202 and the μc-Si unit 204 are patterned in a strip shape. The YAG laser having an energy density of 0.7 J/cm² and a pulse frequency of 3 kHz, for example, is preferably used.

On the μc-Si unit 204, the back surface electrode layer 26 is formed. The method of forming the back surface electrode layer 26 is similar to that in the first embodiment and will therefore not be described. Further, the surface of the back surface electrode layer 26 is covered with the back sheet 30 by using the filler member 28. The filler member 28 and the back sheet can be a resin material such as EVA, polyimide, and the like. With this configuration, intrusion of water content into the power generation layer of the photovoltaic device 206 and the like can be prevented.

Next, with reference to Example 4 and Comparative Examples 3 and 4 in which the surface electrode layer 40 was formed as a single film on the substrate 20 under the film forming conditions shown in Table 6, the advantages which can be obtained by forming the surface electrode layer 40 as a transparent conductive layer including the first transparent conductive region 40a, the second transparent conductive region 40b, and the third transparent conductive region 40c, will be described below. Here, in Example 4, and Comparative Examples 3 and 4, the dopant concentration ratio of the first transparent conductive region 40a, the second transparent conductive region 40b, and the third transparent conductive region 40c was set to 1:0:2.4. Further, the order of film forming and the ratio of film thickness in each region was as shown in Table 7. While the film thickness of each of the first transition region 40d and the second transition region 40e was 5% or more and 10% or less of the total film thickness of the surface electrode layer 40, Table 7 indicates these film thicknesses as being included in the first transparent conductive region 40a, the second transparent conductive region 40b, and the third transparent conductive region 40c.

TABLE 6

| | temperature | pressure | gas flow rate |
|---|---|---|---|
| | (° C.) | (mbar) | (sccm) |
| first transparent | 180 | 0.5 | (C₂H₅) ₂Zn: 650 |
| conductive region 40a, 42a | | | H₂O: 750 |
| | | | B₂H₆: 1.25 |
| | | | H₂: 100 |
| second transparent | 180 | 0.5 | (C₂H₅) ₂Zn: 650 |
| conductive region 40b, 42b | | | H₂O: 750 |
| | | | H₂: 100 |
| third transparent | 180 | 0.5 | (C₂H₅) ₂Zn: 650 |
| conductive region 40c, 42c | | | H₂O: 750 |
| | | | B₂H₆: 3 |
| | | | H₂: 100 |

TABLE 7

| | |
|---|---|
| | film |
| order of film | thickness |
| information | (nm) |

Example 4

| | |
|---|---|
| first | 800 |
| transparent | |
| conductive | |
| region 40a | |
| second | 700 |
| transparent | |
| conductive | |
| region 40b | |
| third | 200 |
| transparent | |
| conductive | |
| region 40c | |

Comparative Example 3

| | |
|---|---|
| first | 1500 |
| transparent | |
| conductive | |
| region 40a | |
| third | 200 |
| transparent | |
| conductive | |
| region 40c | |

Comparative Example 4

| | |
|---|---|
| second | 700 |
| transparent | |
| conductive | |
| region 40b | |
| first | 800 |
| transparent | |
| conductive | |
| region 40a | |
| third | 200 |
| transparent | |
| conductive | |
| region 40c | |

Table 8 shows the measurement results concerning the sheet resistance, the resistivity, and the Haze rate concerning Example 4, and Comparative Examples 3 and 4.

TABLE 8

| | sheet resistance | resistivity | haze rate |
|---|---|---|---|
| | (Ω/□) | (Ωm) | (%) |
| Example 4 | 24.3 | 3.50 × 10⁻⁵ | 22.6 |
| Comparative | 13.6 | 2.11 × 10⁻⁵ | 20.5 |
| Example 3 | | | |
| Comparative | 25.4 | 3.57 × 10⁻⁵ | 17.2 |
| Example 4 | | | |

The Haze rate was used as a performance index of the depressions and projections of the transparent electrode film. The Haze rate is represented by (diffusion transmittance/total transmittance)×100[%] (JIS K7136). Measurements performed with a Haze meter by using a D65 light source or a C light source are generally used as a simple evaluation method of the Haze rate.

When compared to Comparative Example 3, the sheet resistance and the resistivity were higher in Example 4. This is because Example 4 includes the second transparent conductive region 40b having a dopant concentration which is lower than that of the first transparent conductive region 40a, whereas Comparative Example 3 does not include the second transparent conductive region 40b with a low dopant concentration.

On the other hand, the Haze rate is higher in Example 4 that in Comparative Example 3. The lower the dopant concentration, the higher the Haze rate of a transparent conductive film. It can be assumed that this is because the growth of crystal grain is accelerated during film formation to increase the grain size. More specifically, it can be assumed that, in Example 4, by placing the second transparent conductive region 40b between the first transparent conductive region 40a and the third transparent conductive region 40c, the crystal grain in the surface electrode layer 40 is larger than that in Comparative Example 3, and consequently, the depressions and projections of the texture structure of the surface of the surface electrode layer 40 are increased.

Further, when Example 4 is compared to Comparative Example 4, because each of the first transparent conductive region 40a and the second transparent conductive region 40b has an equal film thickness in these examples and only the order of film formation is different, the sheet resistance and the resistivity were substantially equal in these examples.

On the other hand, the Haze rate was higher in Example 4 than in Comparative Example 4. It can be assumed that this is because, in Comparative Example 4, while the crystal grain grows significantly due to the second transparent conductive region 40b having a low dopant concentration during the initial period of film formation of the surface electrode layer 40, the growth of the crystal grain is then lessened due to the first transparent conductive region 40a to be formed subsequently. In Example 4, on the other hand, it can be assumed that after a certain degree of crystal growth has been performed due to the first transparent conductive region 40a, the crystal grain is further increased due to the second transparent conductive region 40b.

Here, by providing the first transition region 40d in which the dopant concentration changes slightly in the film thickness direction in the vicinity of the boundary between the first transparent conductive region 40a and the second transparent conductive region 40b, the adhesion property between the first transparent conductive region 40a and the second transparent conductive region 40b is increased. However, as the light transmittance lowers if the film thickness of the first transition region 40d is too large, it is preferable that the film thickness of the first transition region 40d is 5% or more and 10% or less of the total film thickness of the surface electrode layer 40.

Further, it can be assumed that by providing the second transition region 40e, the crystallinity of the second transparent conductive region 40b serving as a base layer at the time of forming the third transparent conductive region 40c on the second transparent conductive region 40b is taken over and the crystal grain is increased. More specifically, if the change in the dopant concentration at the boundary between the second transparent conductive region 40b and the third transparent conductive region 40c is steep when stacking films having different dopant concentrations, it becomes difficult to take over the crystallinity of the second transparent conductive region 40b at the time of film formation of the third transparent conductive region 40c and the grain size of the third transparent conductive region 40c becomes small. It is therefore preferable to provide the second transition region 40e in which the dopant concentration changes gently in the film thickness direction in the vicinity of the boundary between the second transparent conductive region 40b and the third transparent conductive region 40c. With this configuration, it can be considered that the depressions and projections of the texture structure of the third transparent conductive region 40c are increased to thereby enhance the light scattering property. However, as the light transmittance lowers when the film thickness of the second transition region 40e is too large, it is preferable that the film thickness of the second transition region 40e is 5% or more and 10% or less of the total film thickness of the surface electrode layer 40.

As described above, in Example 4, as the Haze rate is increased so that light incidenting the photovoltaic device 206 is scattered and introduced into the photoelectric conversion unit, the light confinement effect is increased and the photoelectric conversion efficiency of the photovoltaic device 206 can be enhanced.

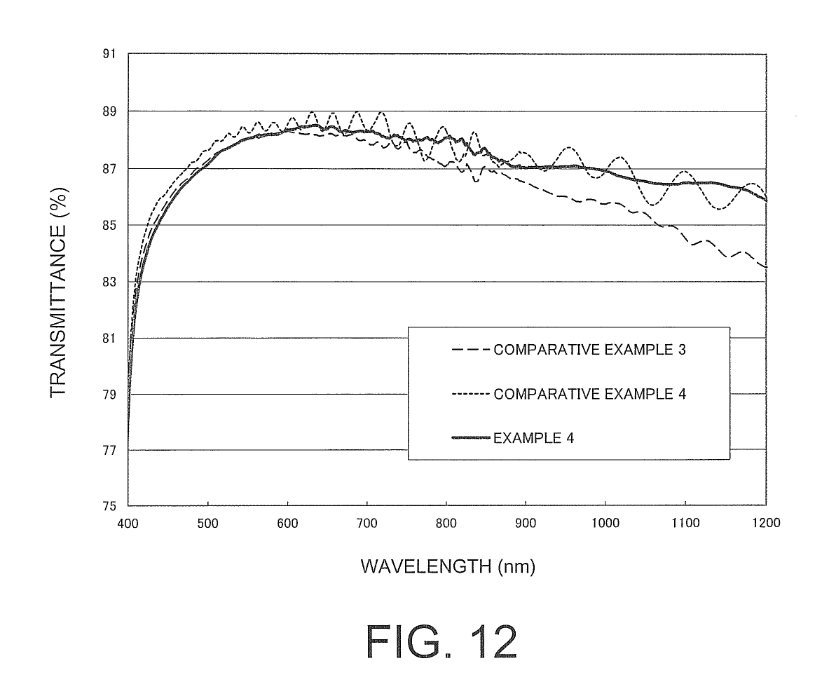

FIG. 12 illustrates the transmittance with respect to the wavelength in Example 4 and Comparative Examples 3 and 4. As illustrated in FIG. 12, when Example 4 is compared to Comparative Example 3, Example 4 exhibited higher transmittance in the long wavelength region of 650 nm or higher. Further, when Example 4 is compared to Comparative Example 4, Example 4 exhibited transmittance which was substantially the same as that of Comparative Example 4.

In a transparent conductive film, the higher the dopant concentration, the lower the transmittance of long wavelength light. Accordingly, it can be assumed that in Comparative Example 3 which does not include the second transparent conductive region 40b having a low dopant concentration, the transmittance was lowered with respect to Example 4 and Comparative Example 4. On the other hand, it can be assumed that in Example 4 and Comparative Example 4, in which the film thickness of each of the first transparent conductive region 40a and the second transparent conductive region 40b is equal in both examples and only the order of forming the films is different, the transmittances were substantially the same.

### Third Embodiment

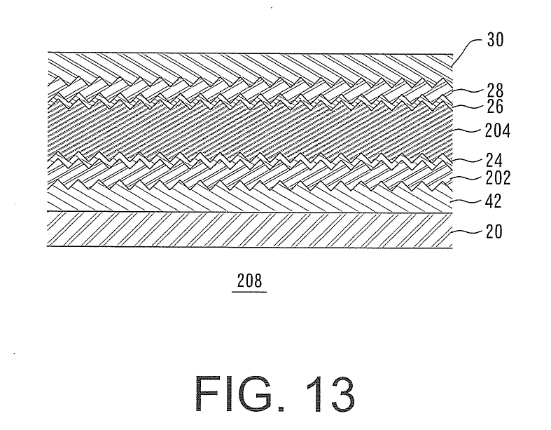

A photovoltaic device 208 according to the third embodiment has a layered structure as illustrated in FIG. 13. Specifically, with a substrate 20 being on a light incidenting side and starting from the light incidenting side, a surface electrode layer 42, an amorphous silicon photoelectric conversion unit (a-Si unit) 202 having a wide band gap as a top cell, an intermediate layer 24, a microcrystalline silicon photoelectric conversion unit (μc-Si unit) 204 having a band gap which is narrower than that of the a-Si unit 202 as a bottom cell, a back surface electrode layer 26, a filler member 28, and a back sheet 30 are stacked.

The surface electrode layer 42 is formed on the substrate 20. The surface electrode layer 42 is formed of a single layer transparent conductive film. The transparent conductive film can be formed by a material and a manufacturing method which are similar to those of the surface electrode layers 22 and 40 described above.

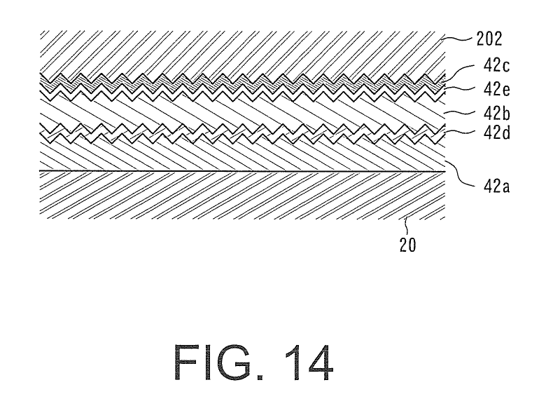

According to the present embodiment, as illustrated in FIG. 14, the surface electrode layer 42 includes a structure in which a first transparent conductive region 42a, a second transparent conductive region 42b, and a third transparent conductive region 42c are stacked sequentially from the substrate 20 side. The first transparent conductive region 42a is provided so as to increase the total conductivity in the surface electrode layer 42. The second transparent conductive region 42b is provided so as to increase the crystal grain in the surface electrode layer 42 to enhance the light scattering effect due to an increase of the depressions and projections in the texture structure. The third transparent conductive region 42c is provided so as to reduce an electrical contact resistance with the layer (the a-Si unit 202) to be formed on the surface electrode layer 42.

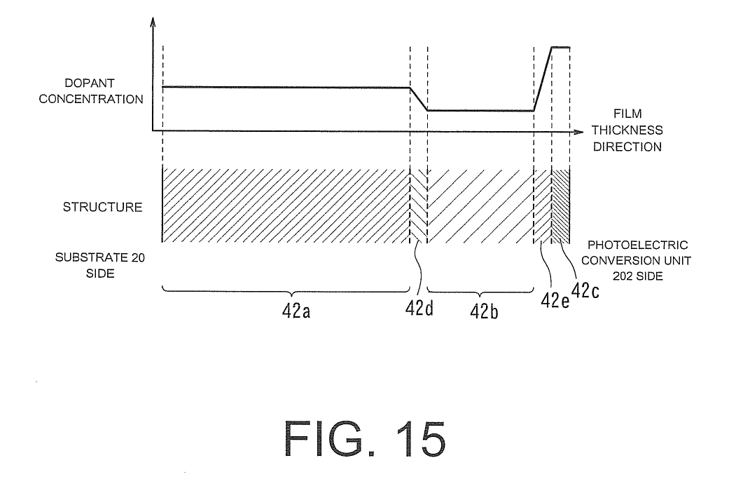

FIG. 15 illustrates a change in the dopant concentration in the film thickness direction of the surface electrode layer 42. It is preferable that the n-type dopant concentration in the film of the second transparent conducive region 42b is equal to half the n-type dopant concentration of the first transparent conductive region 42a or less. However, the second transparent conductive region 42b may be a non-doped region in which no n-type dopant is introduced. Here, a non-doped region refers to a region in which the dopant concentration is less than 1×10¹⁹/cm³ when measured by a secondary-ion mass spectroscopy (SIMS)

Further, it is preferable that the n-type dopant concentration of the third transparent conductive region 42c is equal to twice that of the first transparent conductive region 42a or more. The dopant concentration of the first transparent conductive region 42a is preferably 1×10²⁰/cm³ or less.

By setting the n-type dopant concentration in the film of the second transparent conductive region 42b to be equal to half the n-type dopant concentration of the first transparent conductive region 42a or less, the growth of crystal grain of the second transparent conductive region 42b is accelerated, so that the light scattering effect due to an increase of the depressions and projections of the texture structure can be enhanced.

Further, by setting the n-type dopant concentration of the third transparent conductive region 42c to be equal to twice that of the first transparent conductive region 42a or more, an electrical contact property between the surface electrode layer 42 and the layer to be formed on the surface electrode layer 42 (a-Si unit 202) can be enhanced. Here, when the electrical contact resistance between the surface electrode layer 42 and the layer to be formed on the surface electrode layer 42 (the a-Si unit 202) can be sufficiently reduced, the second transparent conductive region 42c may not necessarily be provided.

Further, it is preferable to provide a first transition region 42d in which the dopant concentration is continuously or discontinuously reduced at the interface between the first transparent conductive region 42a and the second transparent conductive region 42b. Also, it is preferable to provide a second transition region 42e in which the dopant concentration is continuously or discontinuously increased at the interface between the second transparent conductive region 42b and the third transparent conductive region 42c. It can be considered that the first transition region 42d increases the adhesion property between the first transparent conductive region 42b serving as a base layer and the second transparent conductive region 42b and also reduces the contact resistance at the interface thereof. It can be further considered that the second transition region 42e allows the third transparent conductive region 42c to take over the crystallinity or the like of the second transparent conductive region 42b serving as a base layer, so that the light scattering property of the texture structure of the third transparent conductive region 42c can be enhanced.

For example, after forming the first transparent conductive region 42a while introducing doping gas such that the dopant concentration is 1×10²⁰/cm³ or less, the second transparent conductive region 42b is formed by reducing the doping gas such that the dopant concentration of the second transparent conductive region 42b is equal to half that of the first transparent conductive region 42a or less. Further, after forming the second transparent conductive region 42b, the third transparent conductive region 42c is formed by increasing the doping gas such that the dopant concentration of the third transparent conductive region 42c is equal to twice that of the first transparent conductive region 42a or more. The first transition region 42d and the second transition region 42e can be formed with the introduction quantity of the doping gas being varied continuously or discontinuously during film formation.

Here, when the third transparent conductive region 42c is not provided, it is not necessary to provide the second transition region 42e.

The dopant concentration within the surface electrode layer 42 can be measured by secondary ion mass spectroscopy (SIMS). At this time, it is preferable to perform the measurement from the substrate 20 side, in order to avoid effects of the depressions and projections of the crystal grain of the film.

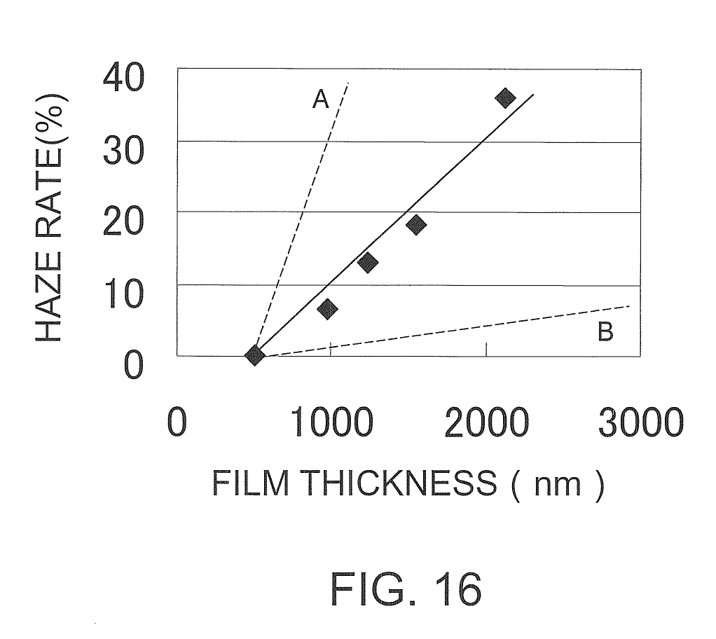

FIG. 16 illustrates a change in the Haze rate of the film of the surface electrode layer 42 with respect to the film thickness when the surface electrode layer 42 is formed as a single film on the substrate 10 (20?). In FIG. 16, the actual values of the Haze rate of the film with respect to the film thickness are indicated by a symbol (♦), and an approximate curve thereof is indicated as a solid line. As illustrated in FIG. 16, the Haze rate does not increase until the film thickness reaches about 500 nm and gradually increases when the film thickness exceeds 500 nm. Also, FIG. 16 illustrates a tendency in which the lower the dopant concentration of the surface electrode layer 42, the closer to the line A the increase rate of the Haze rate approaches, and the higher the dopant concentration of the surface electrode layer 42, the closer to the line B the increase rate of the Haze rate approaches. In other words, the lower the dopant concentration of the surface electrode layer 42, the greater the increase rate of the Haze rate after exceeding the film thickness of 500 nm.

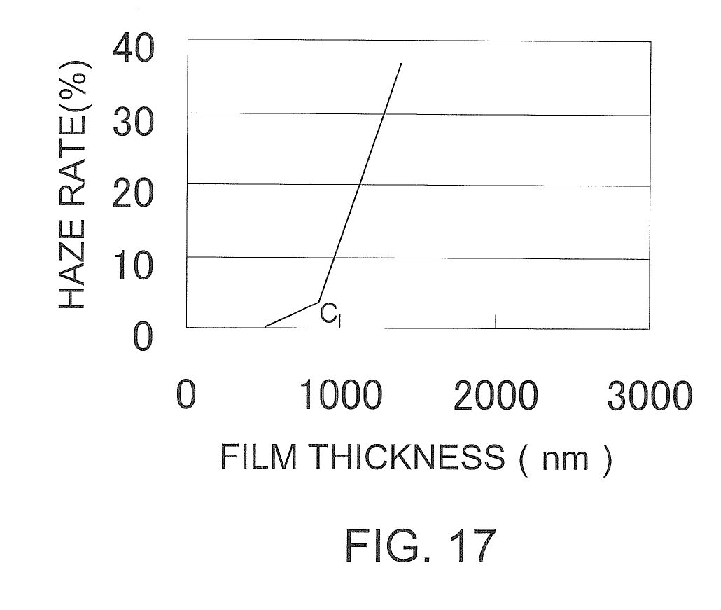

It is therefore preferable of form the second transparent conductive region 42b after forming the first transparent conductive region 42a until the film thickness of the first transparent conductive region 42a becomes 500 nm or more. By forming the first transparent conductive region 42a having a higher dopant concentration than that of the second transparent conductive region 42b to the thickness of at least 500 nm, it is possible to enhance the conductivity of the surface electrode layer 42 as a whole. On the other hand, by forming the second transparent conductive region 42b having a lower dopant concentration with respect to the first transparent conductive region 42a after the film thickness becomes 500 nm or more, it is possible to increase the increase rate of the Haze rate with respect to the film thickness. For example, as illustrated in FIG. 17, the first transparent conductive region 42a is formed until point C at which the film thickness is 500 nm or more is reached, and thereafter, film formation is switched to the second transparent conductive region 42b, thereby achieving the improvement of the increase rate of the Haze rate. Consequently, it is possible to obtain the high Haze rate with a small film thickness of the surface electrode layer 42 as a whole by stacking the second transparent conductive region 42b while securing the conductivity of the surface electrode layer 42 as a whole in the first transparent conductive region 42a to the point of 500 nm where the Haze rate does not change.

It is preferable that the film thickness of the first transparent conductive region 42a is 2000 nm or less. If the film thickness of the first transparent conductive region 42a is unnecessarily large, the quantity of light absorption in the first conductive region 42a increases, which leads to a reduction in the efficiency of the photovoltaic device 100. Further, it is preferable that the film thickness of the second transparent conductive region 42b is 5% or more and 70% or less of the total film thickness of the surface electrode layer 42. If the film thickness of the second transparent conductive region 42b is too large, it is difficult to obtain the effect of the crystal grain growth (=light scattering), whereas if the film thickness of the second conductive region 42b is too small, the resistance of the film increases to thereby result in a reduction in the properties as a transparent conductive film. It is also preferable that the total film thickness of the surface electrode layer 42 is about 2.1 μm.

It is preferable that the film thickness of each of the first transition region 42d and the second transition region 42e is 5% or more and 10% or less of the total film thickness of the surface electrode layer 42. If the film thicknesses of the first transition region 42d and the second transition region 42e are too small, it is difficult to obtain the advantage of increase of the adhesion property and the advantage of taking over the crystallinity, whereas if the film thicknesses are too large, a reduction in the transmittance due to an increased film thickness can be caused.

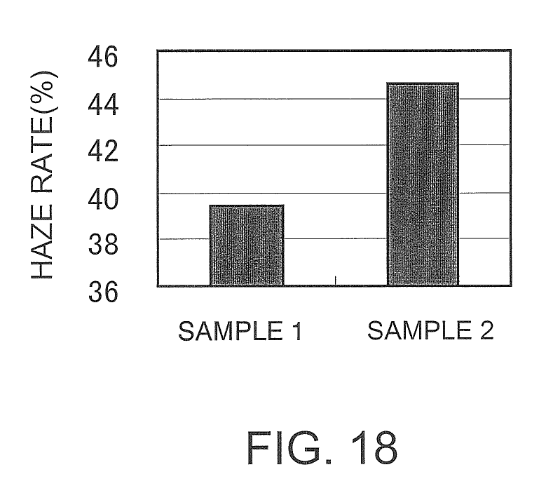

For example, it is preferable that the film thickness of the first transparent conductive region 42a is 1300 nm, the film thickness of the second transparent conductive region 42b is 350 nm, and the film thickness of the third transparent conductive region 42c is 300 nm, under the film forming conditions indicated in Table 6. If the first transition region 42d and the second transition region 42e are provided, the film thickness of each of these regions is preferably 200 nm. In this case, as illustrated as Sample 2 in FIG. 18, the Haze rate exceeded 44. On the other hand, when first forming the second transparent conductive region 42b at a film thickness of 350 nm, and thereafter forming the first transparent conductive region 42a at a film thickness of 1300 nm, and then forming the third transparent conductive region 42c at a film thickness of 30 nm, as illustrated as Sample 1 in FIG. 18, the Haze rate remained about 39.

When the photovoltaic device 208 is configured such that a plurality of cells are connected in series, the surface electrode layer 42 is patterned in a strip shape. For example, it is possible to pattern the surface electrode layer 42 in a strip shape by using a YAG laser having a wavelength of 1064 nm, an energy density of 13 J/cm², and a pulse frequency of 3 kHz.

On the surface electrode layer 42, a p-type layer silicon thin film, an i-type layer silicon thin film, and n-type layer silicon thin film are sequentially stacked to form the a-Si unit 202. On the a-Si unit 202, the intermediate layer 24 is formed. Further, on the intermediate layer 24, the μc-Si unit 204 in which a p-type layer, an i-type layer, and a n-type layer are sequentially stacked is formed. The method of forming these layers are similar to that in the first embodiment and will therefore not be described.

When a plurality of cells are connected in series, the a-Si unit 202, the intermediate layer 24, and the μc-Si unit 204 are patterned in a strip shape. A YAG laser is applied to a position which is laterally displaced from where the surface electrode layer 22 has been patterned by 50 μm to form a slit, and the a-Si unit 202 and the μc-Si unit 204 are patterned in a strip shape. The YAG laser having an energy density of 0.7 J/cm² and a pulse frequency of 3 kHz, for example, is preferably used.

The back surface electrode layer 26 is formed on the μc-Si unit 204. The method of forming the back surface electrode layer 26 is similar to those in the first and second embodiments and will therefore not be described. Further, the surface of the back surface electrode layer 26 is covered with the back sheet 30 by using the filler member 28. The filler member 28 and the back sheet 30 can be a resin material such as EVA, polyimide, and the like. With this configuration, intrusion of water content into the power generation layer of the photovoltaic device 208 and the like can be prevented.

As described above, according to each of the embodiments described above, it is possible to achieve a transparent conductive film having low contact resistance, high electrical conductivity, low light absorption, and high light scattering effect, and by applying this transparent conductive film to the surface electrode layer, it is possible to enhance the properties of the photoelectric conversion device.

### (Appendix)

According to one aspect of the present invention, there is provided a photoelectric conversion device comprising a substrate, a transparent conductive layer formed on the substrate, and a photoelectric conversion unit formed on the transparent conductive layer, wherein the transparent conducive layer includes a first transparent conductive region which is formed on the substrate and has a first boron concentration, a second transparent conductive region which is located toward the photoelectric conversion unit side with respect to the first transparent conductive region and has a second boron concentration which is less than or equal to half the first boron concentration, and a third transparent conductive region which is located further toward the photoelectric conversion unit side with respect to the second transparent conductive region and has a third boron concentration which is more than or equal to the first boron concentration.

According to another aspect of the present invention, there is provided a photoelectric conversion device comprising a substrate, a transparent conductive layer formed on the substrate, and a photoelectric conversion unit formed on the transparent conductive layer, wherein the transparent conducive layer includes a first transparent conductive region which is formed on the substrate and has a first boron concentration, and a second transparent conductive region which is located 500 nm or more distant from the substrate toward the photoelectric conversion unit side and has a second boron concentration which is less than or equal to half the first boron concentration.

### REFERENCE SYMBOLS LIST

10 substrate, 12 surface electrode layer, 14 photoelectric conversion unit, 16 back surface electrode layer, 20 substrate, 22 surface electrode layer, 22a light scattering region, 22b contact region, 24 intermediate layer, 26 back surface electrode layer, 28 filler member, 30 back sheet, 40 surface electrode layer, 40a first transparent conductive region, 40b second transparent conductive region, 40c third transparent conductive region, 40d first transition region, 40e second transition region, 42 surface electrode layer, 42a first transparent conductive region, 42b second transparent conductive region, 42c third transparent conductive region, 22d first transition region, 42e second transition region, 100, 200, 206, 208 photoelectric conversion device.

1.-12. (canceled)

13. A photoelectric conversion device, comprising:
a substrate;
a surface electrode layer which is formed on the substrate; and
a photoelectric conversion unit which is formed on the surface electrode layer,
wherein
the surface electrode layer is formed of a transparent conductive film including dopant, and includes a first transparent conductor region having a first dopant concentration and having a film thickness which is half a total film thickness of the surface electrode layer or more and a second transparent conductor region which is located toward the photoelectric conversion unit with respect to the first transparent conductor region, the second transparent conductor region including a transition region in which a dopant concentration increases continuously from the first transparent conductor region.

14. The photoelectric conversion device according to claim 13, wherein
the second transparent conductor region has a second dopant concentration that is higher than the first dopant concentration and includes a stable region in which a change in the dopant concentration is smaller than that in the transition region.

15. The photoelectric conversion device according to claim 13, wherein
a film thickness of the transition region is one-twentieth or more and one-tenth or less of the total film thickness of the surface electrode layer.

16. The photoelectric conversion device according to claim 13, wherein
the first transparent conductor region is in contact with the substrate, and
the second transparent conductor region is in contact with the photoelectric conversion unit.

17. A photovoltaic device, comprising:
a substrate;
a transparent conductive layer which is formed on the substrate; and
a photoelectric conversion unit which is formed on the transparent conductive layer,
wherein
the transparent conductive layer includes:
a first transparent conductive region which is formed on the substrate and has a first boron concentration;
a second transparent conductive region which is located toward the photoelectric conversion unit with respect to the first transparent conductive region and has a second boron concentration which is half the first boron concentration or less; and
a third transparent conductive region which is located toward the photoelectric conversion unit with respect to the second transparent conductive region and has a third boron concentration which is equal to the first boron concentration or greater.

18. A photovoltaic device, comprising:
a substrate;
a transparent conductive layer which is formed on the substrate; and
a photoelectric conversion unit which is formed on the transparent conductive layer,
wherein
the transparent conductive includes:
a first transparent conductive region which is formed on the substrate and has a first boron concentration; and
a second transparent conductive region which is 500 nm or more separated from the substrate toward the photoelectric conversion unit and has a second boron concentration which is half the first boron concentration or less.

19. The photovoltaic device according to claim 18, wherein the second transparent conductive region is a non-doped region which includes no dopant.

20. The photovoltaic device according to claim 18, comprising:
a third transparent conductive region which is located toward the photoelectric conversion unit with respect to the second transparent conductive region and has a third boron concentration which is equal to the first boron concentration or greater.

21. The photovoltaic device according to claim 17, wherein
a film thickness of the second transparent conductive region is 10% or more and 70% or less of a total film thickness of the transparent conductive layer.

22. The photovoltaic device according to claim 18, wherein
a film thickness of the second transparent conductive region is 10% or more and 70% or less of a total film thickness of the transparent conductive layer.

23. The photovoltaic device according to claim 17, comprising:
a first transition region, between the first transparent conductive region and the second transparent conductive region, which has a boron concentration that transits from the first boron concentration to the second boron concentration and which has a film thickness which is 5% or more and 10% or less of a total film thickness of the transparent conductive layer.

24. The photovoltaic device according to claim 18, comprising:
a first transition region, between the first transparent conductive region and the second transparent conductive region, which has a boron concentration that transits from the first boron concentration to the second boron concentration and which has a film thickness which is 5% or more and 10% or less of a total film thickness of the transparent conductive layer.

25. The photovoltaic device according to claim 17, wherein
the third boron concentration is equal to twice the first boron concentration or more.

26. The photovoltaic device according to claim 20, wherein
the third boron concentration is equal to twice the first boron concentration or more.

27. The photovoltaic device according to claim 17, wherein
the first transparent conductive region is in contact with the substrate, and
the third transparent conductive region is in contact with the photoelectric conversion unit.

28. The photovoltaic device according to claim 20, wherein
the first transparent conductive region is in contact with the substrate, and
the third transparent conductive region is in contact with the photoelectric conversion unit.
